(19) United States
(12) Patent Application Publication
(10) Pub. No.: US 2024/0407176 A1
(43) Pub. Date: Dec. 5, 2024

(54) MAGNETIZATION ROTATION ELEMENT, MAGNETORESISTANCE EFFECT ELEMENT AND MAGNETIC MEMORY

(71) Applicant: TDK Corporation, Tokyo (JP)

(72) Inventors: Yohei SHIOKAWA, Tokyo (JP); Yugo ISHITANI, Tokyo (JP); Kosuke HAMANAKA, Tokyo (JP)

(73) Assignee: TDK Corporation, Tokyo (JP)

(21) Appl. No.: 18/712,336

(22) PCT Filed: Nov. 24, 2021
(86) PCT No.: PCT/JP2021/042874

§ 371 Date: Jul. 29, 2024

(51) Int. Cl. H10B 61/00; H10N 50/10; H10N 50/85

(52) U.S. Cl. CPC H10B 61/00; H10N 50/10; H10N 50/85

(57) ABSTRACT

A magnetization rotation element includes a spin-orbit torque wiring and a first ferromagnetic layer connected to the spin-orbit torque wiring, wherein the spin-orbit torque wiring has a first layer and a second layer, the first layer is closer to the first ferromagnetic layer than the second layer, the first layer has a negative spin Hall angle, and the second layer has a positive spin Hall angle.

### TECHNICAL FIELD

The present disclosure relates to a magnetization rotation element, a magnetoresistance effect element and a magnetic memory.

### BACKGROUND ART

A giant magnetoresistance (GMR) element formed of a multilayer film having a ferromagnetic layer and a non-magnetic layer, and a tunnel magnetoresistance (TMR) element using an insulating layer (tunnel barrier layer, barrier layer) as a non-magnetic layer are known as magnetoresistance effect elements. Magnetoresistance effect elements can be applied to magnetic sensors, high-frequency components, magnetic heads and non-volatile random-access memories (MRAM).

MRAMs are memory elements in which magnetoresistance effect elements are integrated. MRAMs read and write data using a characteristic in which a resistance of a magnetoresistance effect element changes when directions of magnetizations of two ferromagnetic layers with a non-magnetic layer therebetween in the magnetoresistance effect element change. The direction of magnetization of the ferromagnetic layer is controlled using, for example, a magnetic field generated by a current. In addition, for example, the direction of magnetization of the ferromagnetic layer is controlled using a spin transfer torque (STT) generated when a current flows in the lamination direction of magnetoresistance effect elements.

When the direction of magnetization of the ferromagnetic layer is rewritten using an STT, a current flows in the lamination direction of magnetoresistance effect elements. A write current deteriorates characteristics of magnetoresistance effect elements.

In recent years, methods in which there is no need to cause a current to flow in the lamination direction of magnetoresistance effect elements during writing have been focused upon (for example, Patent Document 1). One of the methods is a writing method using a spin-orbit torque (SOT). An SOT is induced by a spin current that is generated by a spin-orbit interaction or the Rashba effect at the interface between dissimilar materials. A current for inducing an SOT in the magnetoresistance effect element flows in a direction crossing the lamination direction of magnetoresistance effect elements. That is, there is no need to cause a current to flow in the lamination direction of magnetoresistance effect elements, and a longer lifespan for magnetoresistance effect elements can be expected.

### CITATION LIST

### Patent Document

[Patent Document 1]
   Japanese Unexamined Patent Application, First Publication No. 2017-216286

### SUMMARY OF DISCLOSURE

### Technical Problem

A magnetoresistance effect element using a SOT writes data when a current flows along the spin-orbit torque wiring. Data is stored by the direction of magnetization of the ferromagnetic layer. The direction of magnetization of the ferromagnetic layer is rewritten by spins injected from the spin-orbit torque wiring. In order to increase the amount of spins injected from the spin-orbit torque wiring into the ferromagnetic layer, there is a need for a magnetization rotation element, a magnetoresistance effect element and a magnetic memory which can generate a spin current with high efficiency.

The present disclosure has been made in view of the above circumstances, and an object of the present disclosure is to provide a magnetization rotation element, a magnetoresistance effect element and a magnetic memory which can generate a spin current with high efficiency.

### Solution to Problem

In order to achieve the above object, the present disclosure provides the following aspects.

(1) A magnetization rotation element according to a first aspect includes a spin-orbit torque wiring and a first ferromagnetic layer connected to the spin-orbit torque wiring. The spin-orbit torque wiring has a first layer and a second layer. The first layer is closer to the first ferromagnetic layer than the second layer. The first layer has a negative spin Hall angle, and the second layer has a positive spin Hall angle.
(2) In the magnetization rotation element according to the above aspect, the first layer may contain a metal element belonging to any one of the group consisting of Group 3, Group 4, Group 5 and Group 6, and the second layer may contain a metal element belonging to any one of the group consisting of Group 8, Group 9, Group 10, Group 11 and Group 12.
(3) In the magnetization rotation element according to the above aspect, the second layer may contain a light element with an atomic number of 38 or less.
(4) In the magnetization rotation element according to the above aspect, at least one of the first layer and the second layer may contain any one of the group consisting of oxygen, nitrogen, and carbon.
(5) In the magnetization rotation element according to the above aspect, the contents of oxygen, nitrogen and carbon in the second layer may be all 50 atm % or less.
(6) The magnetization rotation element according to the above aspect may further include an intermediate layer between the first layer and the second layer.
(7) In the magnetization rotation element according to the above aspect, the intermediate layer may contain a ferromagnetic material.
(8) In the magnetization rotation element according to the above aspect, the thickness of the intermediate layer may be 1 nm or less.
(9) In the magnetization rotation element according to the above aspect, the intermediate layer may contain any one of the group consisting of Ir, Ru, Rh, Cr, Cu, Re, Pd, Pt, and Au.
(10) A magnetoresistance effect element according to a second aspect includes the magnetization rotation element according to the above aspect, a non-magnetic layer, and a second ferromagnetic layer, wherein the non-magnetic layer is interposed between the first ferromagnetic layer and the second ferromagnetic layer, and wherein the first ferromagnetic layer is closer to the spin-orbit torque wiring than the second ferromagnetic layer.
(11) A magnetic memory according to a third aspect includes the plurality of magnetoresistance effect elements according to the above aspect.

### Advantageous Effects of Disclosure

The magnetization rotation element, magnetoresistance effect element and magnetic memory according to the present disclosure can generate a spin current with high efficiency.

### BRIEF DESCRIPTION OF DRAWINGS

FIG. 1 is a circuit diagram of a magnetic memory according to a first embodiment.

FIG. 2 is a cross-sectional view of a feature part of the magnetic memory according to the first embodiment.

FIG. 3 is a cross-sectional view of a magnetoresistance effect element according to the first embodiment.

FIG. 4 is a plan view of the magnetoresistance effect element according to the first embodiment.

FIG. 5 is a cross-sectional view of a magnetoresistance effect element according to a first modification example.

FIG. 6 is a cross-sectional view of a magnetoresistance effect element according to a second modification example.

FIG. 7 is a cross-sectional view of a magnetization rotation element according to a second embodiment.

### DESCRIPTION OF EMBODIMENTS

The present embodiment will be appropriately described below in detail with reference to the drawings. In the drawings used in the following description, in order to facilitate understanding of features of the present disclosure, feature parts are enlarged for convenience of illustration in some cases, and size ratios and the like of components may be different from those of actual components. Materials, sizes and the like provided in the following description are merely exemplary examples, the present disclosure is not limited thereto, and they can be appropriately changed and implemented within a range in which the effects of the present disclosure are obtained.

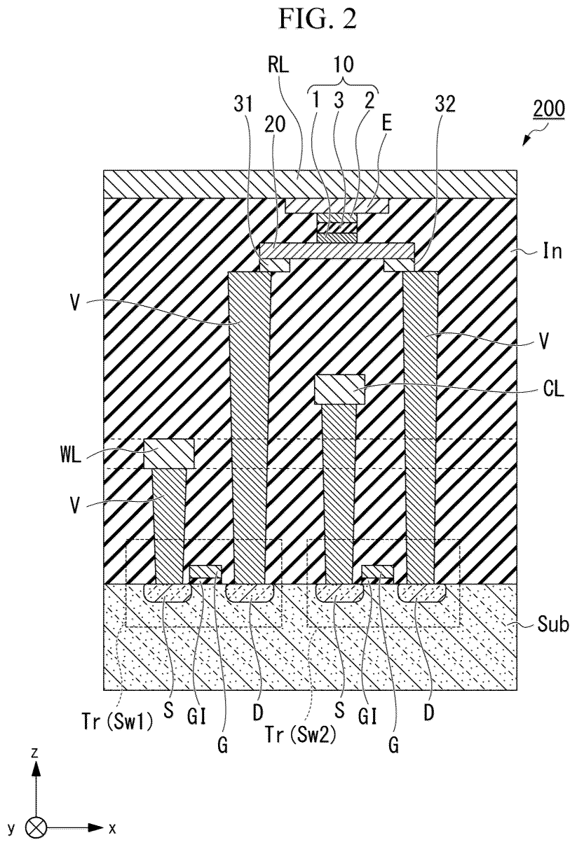

First, directions will be defined. On one surface of a substrate Sub (refer to FIG. 2) to be described below, one direction is defined as an x direction, and a direction orthogonal to the x direction is defined as a y direction. The x direction is, for example, a longitudinal direction of a spin-orbit torque wiring 20. The z direction is a direction orthogonal to the x direction and the y direction. The z direction is an example of a lamination direction in which respective layers are laminated. Hereinafter, the +z direction may be expressed as “upward,” and the −z direction may be expressed as “downward.” Upward and downward may not always be aligned with the direction of gravity.

For example, “extend in the x direction” in this specification means that the size in the x direction is larger than the smallest size in the x direction, the y direction, and the z direction. The same applies to extension in other directions. In addition, “connection” in this specification is not limited to physical connection. For example, “connection” is not limited to a case in which two layers are physically in contact with each other, and also includes a case in which two layers are connected with another layer therebetween. In addition, “connection” in this specification also includes electrical connection.

### First Embodiment

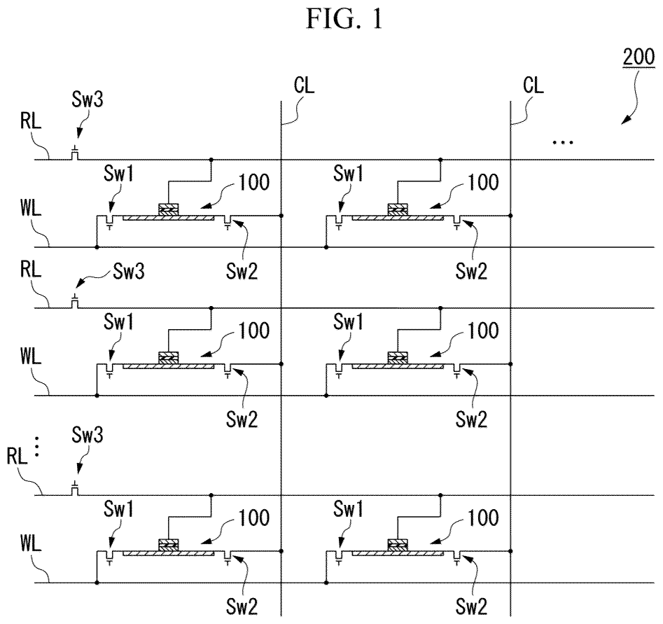

FIG. 1 is a configuration diagram of a magnetic memory 200 according to a first embodiment. The magnetic memory 200 includes a plurality of magnetoresistance effect elements 100, a plurality of write wirings WL, a plurality of common wirings CL, a plurality of read wirings RL, a plurality of first switching elements Sw1, a plurality of second switching elements Sw2, and a plurality of third switching elements Sw3. The magnetic memory 200 includes, for example, the magnetoresistance effect elements 100 arranged in an array.

Each write wiring WL electrically connects a power source to one or more magnetoresistance effect elements 100. Each common wiring CL is a wiring used both during writing and reading of data. Each common wiring CL electrically connects a reference potential to one or more magnetoresistance effect elements 100. The reference potential is, for example, the ground. The common wiring CL may be disposed in each of the plurality of magnetoresistance effect elements 100, and may be disposed for a plurality of magnetoresistance effect elements 100. Each read wiring RL electrically connects a power source to one or more magnetoresistance effect elements 100. The power source is connected to the magnetic memory 200 during use.

Each magnetoresistance effect element 100 is connected to each of the first switching element Sw1, the second switching element Sw2, and the third switching element Sw3. The first switching element Sw1 is connected between the magnetoresistance effect element 100 and the write wiring WL. The second switching element Sw2 is connected between the magnetoresistance effect element 100 and the common wiring CL. The third switching element Sw3 is connected to the read wiring RL for a plurality of magnetoresistance effect elements 100.

When a predetermined first switching element Sw1 and second switching element Sw2 are turned ON, a write current flows between the write wiring WL and the common wiring CL which are connected to the predetermined magnetoresistance effect element 100. When a write current flows, data is written in the predetermined magnetoresistance effect element 100. When a predetermined second switching element Sw2 and third switching element Sw3 are turned ON, a read current flows between the common wiring CL and the read wiring RL, which are connected to the predetermined magnetoresistance effect element 100. When a read current flows, data is read from the predetermined magnetoresistance effect element 100.

The first switching element Sw1, the second switching element Sw2 and the third switching element Sw3 are elements that control a flow of a current. The first switching element Sw1, the second switching element Sw2 and the third switching element Sw3 are, for example, a transistor, an element using a phase change of a crystal layer such as an ovonic threshold switch (OTS), an element using a change in band structure such as a metal insulator transition (MIT) switch, an element using a breakdown voltage such as a Zener diode and an avalanche diode, and an element of which conductivity changes as the atomic position changes.

In the magnetic memory 200 shown in FIG. 1, the magnetoresistance effect elements 100 connected to the same read wiring RL share the third switching element Sw3. The third switching element Sw3 may be disposed in each of the magnetoresistance effect elements 100. In addition, the third switching element Sw3 may be disposed in each magnetoresistance effect element 100, and the first switching element Sw1 or the second switching element Sw2 may be shared by the magnetoresistance effect element 100 connected to the same wiring.

FIG. 2 is a cross-sectional view of a feature part of the magnetic memory 200 according to the first embodiment. FIG. 2 shows a cross section of the magnetoresistance effect element 100 cut along an xz plane that passes through the center of the width of the spin-orbit torque wiring 20 to be described below in the y direction.

The first switching element Sw1 and the second switching element Sw2 shown in FIG. 2 are transistors Tr. The third switching element Sw3 is electrically connected to the read wiring RL, and is positioned, for example, in the x direction in FIG. 2. The transistor Tr is, for example, a field-effect transistor, and includes a gate electrode G, a gate insulating film GI, and a source S and a drain D formed on the substrate Sub. The source S and the drain D are defined by a current flow direction, and these are the same region. The positional relationship between the source S and the drain D may be reversed. The substrate Sub is, for example, a semiconductor substrate.

The transistor Tr and the magnetoresistance effect element 100 are electrically connected via a via wiring V, a first wiring 31 and a second wiring 32. In addition, the transistor Tr and the write wiring WL or the common wiring CL are connected via a via wiring V. The via wiring V extends, for example, in the z direction. The read wiring RL is connected to a laminate 10 via an electrode E. The via wiring V and the electrode E contain a conductive material. The via wiring V and the first wiring 31 may be integrated. In addition, the via wiring V and the second wiring 32 may be integrated. That is, the first wiring 31 may be a part of the via wiring V, and the second wiring 32 may be a part of the via wiring V.

The circumference of the magnetoresistance effect element 100 and the transistor Tr is covered with an insulating layer In. The insulating layer In is an insulating layer that insulates between wirings of multi-layer wirings and between elements. The insulating layer In is made of, for example, silicon oxide (SiOₓ), silicon nitride (SiNₓ), silicon carbide (SiC), silicon carbonitride (SiCN), silicon oxynitride (SiON), aluminum oxide (Al₂O₃), zirconium oxide (ZrOₓ), magnesium oxide (MgO), or aluminum nitride (AlN).

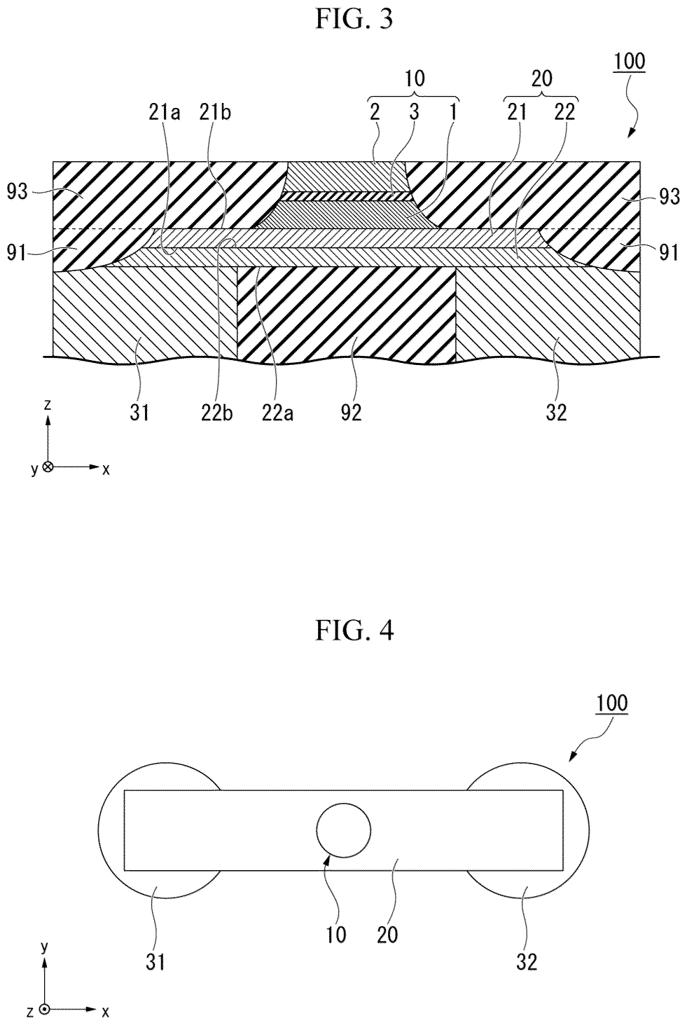

FIG. 3 is a cross-sectional view of the magnetoresistance effect element 100. FIG. 3 shows a cross section of the magnetoresistance effect element 100 cut along an xz plane that passes through the center of the width of the spin-orbit torque wiring 20 in the y direction. FIG. 4 is a plan view of the magnetoresistance effect element 100 when viewed in the z direction.

The magnetoresistance effect element 100 includes, for example, the laminate 10, the spin-orbit torque wiring 20, the first wiring 31 and the second wiring 32. The laminate 10 has a first ferromagnetic layer 1, a second ferromagnetic layer 2 and a non-magnetic layer 3. The circumference of the magnetoresistance effect element 100 is covered with, for example, a first insulating layer 91, a second insulating layer 92, and a third insulating layer 93. The first insulating layer 91, the second insulating layer 92 and the third insulating layer 93 are parts of the above insulating layer In.

The first insulating layer 91 is on the same level as the spin-orbit torque wiring 20. The first insulating layer 91 extends, for example, in the xy plane. The first insulating layer 91 surrounds the circumference of the spin-orbit torque wiring 20 in a plan view from the z direction. The second insulating layer 92 is on the same level as the first wiring 31 and the second wiring 32. The second insulating layer 92 extends, for example, in the xy plane. The second insulating layer 92 surrounds the circumference of the first wiring 31 and the second wiring 32 in a plan view from the z direction. The third insulating layer 93 is on the same level as the laminate 10. The third insulating layer 93 extends, for example, in the xy plan. The third insulating layer 93 surrounds the circumference of the laminate 10 in a plan view from the z direction. For example, the third insulating layer 93 is in contact with the laminate 10.

The magnetoresistance effect element 100 is a magnetic element using a spin-orbit torque (SOT), and is sometimes referred to as a spin-orbit torque type magnetoresistance effect element, a spin injection type magnetoresistance effect element, or a spin current magnetoresistance effect element.

The magnetoresistance effect element 100 is an element that records and stores data. The magnetoresistance effect element 100 records data based on the resistance value of the laminate 10 in the z direction. The resistance value of the laminate 10 in the z direction changes when a write current is applied along the spin-orbit torque wiring and a spin is injected to the laminate 10 from the spin-orbit torque wiring 20. The resistance value of the laminate 10 in the z direction can be read by applying a read current to the laminate 10 in the z direction.

The first wiring 31 and the second wiring 32 are connected to the spin-orbit torque wiring 20 at positions where the first ferromagnetic layer 1 is between them when viewed in the z direction. Another layer may be disposed between the first wiring 31 and the spin-orbit torque wiring 20, and between the second wiring 32 and the spin-orbit torque wiring 20.

The first wiring 31 and the second wiring 32 are, for example, conductors that electrically connect the switching element and the magnetoresistance effect element 100. Both the first wiring 31 and the second wiring 32 have conductivity. The first wiring 31 and the second wiring 32 contain, for example, any selected from the group consisting of Ti, Cr, Cu, Mo, Ru, Ta, and W.

For example, the spin-orbit torque wiring 20 has a longer length in the x direction than in the y direction when viewed in the z direction and extends in the x direction. The write current flows between the first wiring 31 and the second wiring 32 in the x direction along the spin-orbit torque wiring 20. The spin-orbit torque wiring 20 is connected to each of the first wiring 31 and the second wiring 32.

The spin-orbit torque wiring 20 causes a spin current to be generated due to the spin Hall effect when a current flows, and a spin to be injected into the first ferromagnetic layer 1. The spin-orbit torque wiring 20 applies, for example, a spin-orbit torque (SOT) with which the magnetization of the first ferromagnetic layer 1 can be reversed to the magnetization of the first ferromagnetic layer 1.

The spin Hall effect is a phenomenon in which, when a current flows, a spin current is induced in a direction orthogonal to a direction in which the current flows due to a spin-orbit interaction. The spin Hall effect and a general Hall effect are the same in that mobile (moving) charges (electrons) are bent in the direction of motion (movement). In the general Hall effect, a movement direction of charged particles that move in a magnetic field is bent due to a Lorentz force. On the other hand, in the spin Hall effect, a movement direction of a spin is bent only by movement of electrons (only when a current flows) without there being a magnetic field.

A spin current is generated by eliminating uneven distribution (spin polarization) of spins. For example, when a current flows through a wiring, spins (for example, +spins) oriented in the first direction are unevenly distributed on the first surface of the wiring, and spins (for example, −spins) oriented in the direction opposite to the first direction are unevenly distributed on the second surface that faces the first surface. In order to eliminate this spin uneven distribution, a spin current is generated from the first surface toward the second surface or from the second surface toward the first surface. Both the +spins and the −spins are electrons, and flows of charges cancel each other out, and thus no current is generated between the first surface and the second surface.

Whether the spin current is generated from the first surface toward the second surface or generated from the second surface toward the first surface depends on the polarity of the spin Hall angle of the wiring through which a current flows. When the polarity of the spin Hall angle differs, the signs of spins that are unevenly distributed on the first surface and the second surface are reversed. Therefore, when the wiring has a negative spin Hall angle, for example, when a spin current is generated from the first surface toward the second surface, and the wiring has a positive spin Hall angle, for example, a spin current is generated from the second surface toward the first surface. The “spin Hall angle” is one indicator for the strength of the spin Hall effect, and indicates the conversion efficiency of the spin current generated with respect to the current that flows through the wiring.

The spin-orbit torque wiring 20 has a first layer 21 and a second layer 22. The first layer 21 is closer to the first ferromagnetic layer 1 than the second layer 22. For example, the first layer 21 and the second layer 22 are in direct contact with each other. The first layer 21 and the second layer 22 each extend in the x direction. Parts of the first layer 21 and the second layer 22 overlap the first wiring 31 and the second wiring 32 when viewed in the z direction.

The first layer 21 and the second layer 22 have different spin Hall angle polarities. Since the polarity of the spin Hall angle is determined according to the electron state of the layer, it changes depending on the material constituting the layer, the thickness of the layer, adjacent materials, and the like which determine the electron state. For example, the polarity of the material constituting the layer may change when a plurality of elements are solid-solutionized such as in an alloy, and the polarity may change when the material becomes a compound by oxidation, nitridation, or carbonization. In addition, the polarity may also change when the electron state is macroscopically changed by laminating different materials. Furthermore, the polarity of the spin Hall angle may change depending on the thickness of the layer.

The first layer 21 has a negative spin Hall angle. For example, when a current flows along the first layer 21 in the x direction, +spins are unevenly distributed on a first surface 21a, and −spins are unevenly distributed on a second surface 21b. As a result, in the first layer 21, for example, a spin current is generated from the first surface 21a toward the second surface 21b.

The second layer 22 has a positive spin Hall angle. For example, when a current flows along the second layer 22 in the x direction, +spins are unevenly distributed on a second surface 22b, and −spins are unevenly distributed on a first surface 22a. As a result, in the second layer 22, for example, a spin current is generated from the second surface 22b toward the first surface 22a.

When the polarities of the spin Hall angles of the first layer 21 and the second layer 22 are different, uneven distribution of spins at the interface between the first layer 21 and the second layer 22 (the first surface 21a, the second surface 22b) becomes stronger. As a result, a spin current can be efficiently generated in the first layer 21, and a spin can be efficiently injected into the first ferromagnetic layer 1.

The first layer 21 contains any of metals, alloys, intermetallic compounds, metal borides, metal carbides, metal silicides, metal phosphides, and metal nitrides which have a function of generating a pure spin current due to the spin Hall effect when a current flows.

The first layer 21 may be made of, for example, a non-magnetic heavy metal. Here, the heavy metal is a metal having a specific gravity that is equal to or higher than that of yttrium. The non-magnetic heavy metal is, for example, a non-magnetic metal including d electrons or f electrons in the outermost shell and having a large atomic number of 39 or more. These non-magnetic metals have a large spin-orbit interaction that causes the spin Hall effect.

The first layer 21 contains, for example, a metal element belonging to any one of the group consisting of Group 3, Group 4, Group 5 and Group 6. The first layer 21 mainly contains, for example, a metal element belonging to any one of the group consisting of Group 3, Group 4, Group 5 and Group 6. “Mainly contain” means that the content of these metal elements is 50 atm % or more.

The first layer 21 contains, for example, a non-magnetic heavy metal belonging to any one of the group consisting of Group 3, Group 4, Group 5 and Group 6. The first layer 21 contains, for example, tungsten (W).

In addition, the first layer 21 may contain oxygen, nitrogen, or carbon. When the layer contains oxygen, nitrogen, or carbon, the spin diffusion efficiency increases. The first layer 21 may be made of, for example, an oxide, nitride, or carbide of a metal belonging to any of Group 3, Group 4, Group 5 and Group 6. For example, the first layer 21 contains tantalum nitride (TaN).

When the first layer 21 contains oxygen, nitrogen, or carbon, it is preferable that the contents of oxygen, nitrogen and carbon be all 50 atm % or less. In addition, the content of oxygen, nitrogen, or carbon contained in the first layer 21 is preferably, for example, 30 atm % or more. When these contents are within this range, the compound belongs to a stable phase in the phase diagram, and the compound is stabilized.

The content of these elements is determined by the following procedure. The nitrogen content can be measured, for example, through energy-dispersive X-ray spectroscopy (EDS) or electron energy loss spectroscopy (EELS) using a transmission electron microscope (TEM). For example, when EDS composition mapping or EELS composition mapping is performed on the spin-orbit torque wiring 20 formed into a thin piece to 20 nm or less in the Y direction with an electron beam diameter of 1 nm or less, it is possible to determine the nitrogen content of each wiring. When the thickness of the thin piece is thicker than 20 nm, since depth composition information is superimposed, each wiring may be measured not as a layer but as an uneven distribution. In addition, even when the electron beam diameter is larger than 1 nm, since the energies of adjacent elements are superimposed, each wiring may be measured not as a layer but as an uneven distribution. Since the boundaries between the spin-orbit torque wiring, the first wiring, and the second wiring are finite electron lines, the nitrogen distribution may appear continuously.

The thickness of the first layer 21 may be, for example, equal to or more than the spin diffusion length of the material constituting the first layer 21. When this condition is satisfied, spins that are generated in the second layer 22 and are in a direction opposite to spins injected from the first layer 21 into the first ferromagnetic layer 1 can be prevented from reaching the first ferromagnetic layer 1 via the first layer 21. The thickness of the first layer 21 is, for example, 4 nm or more. The thickness of the first layer 21 may be, for example, for example, 20 nm or less.

The second layer 22 contains any of metals, alloys, intermetallic compounds, metal borides, metal carbides, metal silicides, metal phosphides, and metal nitrides which have a function of generating a pure spin current due to the spin Hall effect when a current flows.

The second layer 22 may be made of, for example, a non-magnetic heavy metal. The second layer 22 contains, for example, a metal element belonging to any of Group 8, Group 9, Group 10, Group 11 and Group 12. The second layer 22 mainly contains, for example, a metal element belonging to any of Group 8, Group 9, Group 10, Group 11 and Group 12.

In addition, the second layer 22 may contain oxygen, nitrogen, or carbon. The second layer 22 may be made of, for example, an oxide, nitride, or carbide of a metal belonging to any of Group 8, Group 9, Group 10, Group 11 and Group 12.

The second layer 22 may contain a light element with an atomic number of 38 or less, regardless of the group of the periodic table. The second layer 22 may be made of, for example, an oxide, nitride, or carbide of a light element with an atomic number of 38 or less. Light elements generally have a small spin-orbit interaction and are less likely to cause the spin Hall effect. On the other hand, light elements can exhibit a sufficient spin Hall effect by forming oxides, nitrides, and carbides. For example, the second layer 22 contains titanium nitride (TiN).

When the second layer 22 contains oxygen, nitrogen, or carbon, it is preferable that the contents of oxygen, nitrogen and carbon be all 50 atm % or less. In addition, the content of oxygen, nitrogen, or carbon contained in the second layer 22 is preferably, for example, 30 atm % or more.

The thickness of the second layer 22 is preferably, for example, 1 nm or more and 20 nm or less. When the thickness is less than 1 nm, grains are often present without forming a layer, and it is not possible to efficiently flow a current through the second layer 22. In addition, when the thickness is thicker than 20 nm, the surface of the second layer 22 becomes rough, the interfacial resistance that does not contribute to generation of spins generated at the interface with the first layer 21 or the interface with the wiring 31 or the wiring 32 increases, and spin current generation efficiency may deteriorate.

The resistivity of the spin-orbit torque wiring 20 is, for example, 1 mΩ·cm or more. In addition, the resistivity of the spin-orbit torque wiring 20 is, for example, 10 mΩ·cm or less. When the resistivity of the spin-orbit torque wiring 20 is high, a high voltage can be applied to the spin-orbit torque wiring 20. When the potential of the spin-orbit torque wiring 20 is high, a spin can be efficiently supplied from the spin-orbit torque wiring 20 to the first ferromagnetic layer 1. In addition, when the spin-orbit torque wiring 20 has a certain level or more of conductivity, a path through which a current flows along the spin-orbit torque wiring 20 can be secured, and a spin current due to the spin Hall effect can be efficiently generated. The resistivity of the first wiring 31 and the second wiring 32 is preferably lower than the resistivity of the spin-orbit torque wiring 20.

In addition to this, the spin-orbit torque wiring 20 may contain a magnetic metal or a topological insulator. The topological insulator is a substance which includes an insulator or a high resistance component therein and has a spin-polarized metallic state on its surface.

The laminate 10 is connected to the spin-orbit torque wiring 20. For example, the laminate 10 is laminated on the spin-orbit torque wiring 20. Another layer may be disposed between the laminate 10 and the spin-orbit torque wiring 20.

The resistance value of the laminate 10 in the z direction changes when a spin is injected from the spin-orbit torque wiring 20 into the laminate 10 (the first ferromagnetic layer 1).

The laminate 10 is interposed between the spin-orbit torque wiring 20 and the electrode E in the z direction (refer to FIG. 2). The laminate 10 is a columnar component. The shape of the laminate 10 in a plan view in the z direction is, for example, a circular shape, an elliptical shape or a rectangular shape. For example, the side surface of the laminate 10 is inclined with respect to the z direction.

The laminate 10 has, for example, the first ferromagnetic layer 1, the second ferromagnetic layer 2, and the non-magnetic layer 3. For example, the first ferromagnetic layer 1 is in contact with the spin-orbit torque wiring 20, and is laminated on the spin-orbit torque wiring 20. A spin is injected into the first ferromagnetic layer 1 from the spin-orbit torque wiring 20. The magnetization of the first ferromagnetic layer 1 receives a spin-orbit torque (SOT) and the orientation direction changes due to the injected spin. The non-magnetic layer 3 is inserted between the first ferromagnetic layer 1 and the second ferromagnetic layer 2 in the z direction.

The first ferromagnetic layer 1 and the second ferromagnetic layer 2 each have a magnetization. The orientation direction of the magnetization of the second ferromagnetic layer 2 is less likely to change than the magnetization of the first ferromagnetic layer 1 when a predetermined external force is applied. The first ferromagnetic layer 1 may be called a magnetization free layer, and the second ferromagnetic layer 2 may called a magnetization fixed layer or a magnetization reference layer. In the laminate 10 shown in FIG. 3, the magnetization fixed layer is on the side away from the substrate Sub and is called a top pin structure. The resistance value of the laminate 10 changes according to a difference in the relative angle between the magnetizations of the first ferromagnetic layer 1 and the second ferromagnetic layer 2 with the non-magnetic layer 3 therebetween.

The first ferromagnetic layer 1 and the second ferromagnetic layer 2 contain a ferromagnetic material. Examples of ferromagnetic materials include a metal selected from the group consisting of Cr, Mn, Co, Fe and Ni, an alloy containing one or more of these metals, and an alloy containing such a metal and at least one or more elements of B, C, and N. The ferromagnetic material is, for example, a Co—Fe, Co—Fe—B, Ni—Fe, or Co—Ho alloy, an Sm—Fe alloy, an Fe—Pt alloy, a Co—Pt alloy, or a CoCrPt alloy.

The first ferromagnetic layer 1 and the second ferromagnetic layer 2 may contain a heusler alloy. A heusler alloy contains an intermetallic compound having a chemical composition of XYZ or X₂YZ. In the periodic table, X is a transition metal element from the Co, Fe, Ni, or Cu groups or a noble metal element, Y is a transition metal from the Mn, V, Cr or Ti groups or an element of type X, and Z is a typical element from Group III to Group V. Examples of heusler alloys include Co₂FeSi, Co₂FeGe, Co₂FeGa, Co₂MnSi, CO₂Mn₁₋ₐFeₐAl_{b}Si_{1-b}, and Co₂FeGe_{1-c}Ga_{c}. Heusler alloys have a high spin polarizability.

The non-magnetic layer 3 contains a non-magnetic component. When the non-magnetic layer 3 is an insulator (when it is a tunnel barrier layer), as its material, for example, Al₂O₃, SiO₂, MgO, and MgAl₂O₄ can be used. In addition, in addition to these materials, materials in which some of Al, Si, and Mg is replaced with Zn, Be or the like can also be used. Among these, MgO and MgAl₂O₄ are materials that can realize coherent tunneling and thus they can efficiently inject spins. When the non-magnetic layer 3 is made of a metal, Cu, Au, Ag or the like can be used as its material. In addition, when the non-magnetic layer 3 is a semiconductor, Si, Ge, CuInSe₂, CuGaSe₂, Cu(In,Ga)Se₂ or the like can be used as its material.

The laminate 10 may have a layer other than the first ferromagnetic layer 1, the second ferromagnetic layer 2 and the non-magnetic layer 3. For example, a base layer may be disposed between the spin-orbit torque wiring 20 and the first ferromagnetic layer 1. The base layer increases the crystallinity of each layer constituting the laminate 10. In addition, for example, a cap layer may be disposed on the uppermost surface of the laminate 10.

In addition, the laminate 10 may have a ferromagnetic layer on the surface of the second ferromagnetic layer 2 opposite to the non-magnetic layer 3 with a spacer layer therebetween. The second ferromagnetic layer 2, the spacer layer, and the ferromagnetic layer form a synthetic antiferromagnetic structure (SAF structure). The synthetic antiferromagnetic structure is formed of two magnetic layers with a non-magnetic layer therebetween. Due to antiferromagnetic coupling between the second ferromagnetic layer 2 and the ferromagnetic layer, a coercive force of the second ferromagnetic layer 2 becomes larger compared to when there is no ferromagnetic layer. The ferromagnetic layer is made of, for example, IrMn, PtMn or the like. The spacer layer contains, for example, at least one selected from the group consisting of Ru, Ir, and Rh.

Next, a method of producing the magnetoresistance effect element 100 will be described. The magnetoresistance effect element 100 is formed according to a step of laminating layers and a processing step of processing a part of each layer into a predetermined shape. The layers can be laminated using a sputtering method, a chemical vapor deposition (CVD) method, an electron beam evaporation method (EB evaporation method), an atomic laser deposition method or the like. The layers can be processed using photolithography or the like.

First, impurities are doped at a predetermined position on the substrate Sub to form the source S and the drain D. Next, the gate insulating film GI and the gate electrode G are formed between the source S and the drain D. The source S, the drain D, the gate insulating film GI and the gate electrode G form the transistor Tr. As the substrate Sub, a commercially available semiconductor circuit substrate on which a transistor Tr is formed may be used.

Next, the insulating layer In is formed so that the transistor Tr is covered. In addition, when an opening is formed in the insulating layer In and a conductor is filled into the opening, the via wiring V, the first wiring 31 and the second wiring 32 are formed. The write wiring WL and the common wiring CL are formed when the insulating layer In is laminated to a predetermined thickness, a groove is then formed in the insulating layer In, and a conductor is filled into the groove.

Next, on one surface of the insulating layer In, the first wiring 31 and the second wiring 32, a layer that will become the second layer 22 and a layer that will become the first layer 21 are laminated in order. When the material and thickness of each layer are designed, the polarity of the spin Hall angle of the first layer 21 and the second layer 22 can be set.

Next, on the layer that will become the second layer 22, a ferromagnetic layer, a non-magnetic layer, a ferromagnetic layer, and a hard mask layer are laminated in order. Next, the hard mask layer is processed into a predetermined shape. The predetermined shape is, for example, the outer shape of the spin-orbit torque wiring 20. Next, a layer that will become the spin-orbit torque wiring 20, the ferromagnetic layer, the non-magnetic layer, and the ferromagnetic layer are processed into a predetermined shape at one time through the hard mask layer.

Next, an unnecessary part of the hard mask layer in the x direction is removed. The hard mask layer forms the outer shape of the laminate 10. Next, an unnecessary part of the laminate formed on the spin-orbit torque wiring 20 in the x direction is removed through the hard mask layer. The laminate 10 is processed into a predetermined shape and the laminate 10 is obtained. The hard mask layer becomes the electrode E. Next, the circumference of the laminate 10 and the spin-orbit torque wiring is filled with the insulating layer In, and the magnetoresistance effect element 100 is obtained.

The magnetoresistance effect element 100 according to the first embodiment can increase uneven distribution of spins in the first layer 21 by laminating layers with different polarities of spin Hall angles. Since the spin current is generated to eliminate uneven distribution of spins, the magnetoresistance effect element 100 according to the first embodiment can efficiently generate a spin current.

While an example of the magnetoresistance effect element 100 according to the first embodiment has been described above, additions, omissions, substitutions and other modifications of the configurations can be made without departing from the spirt and scope of the present disclosure.

### First Modification Example

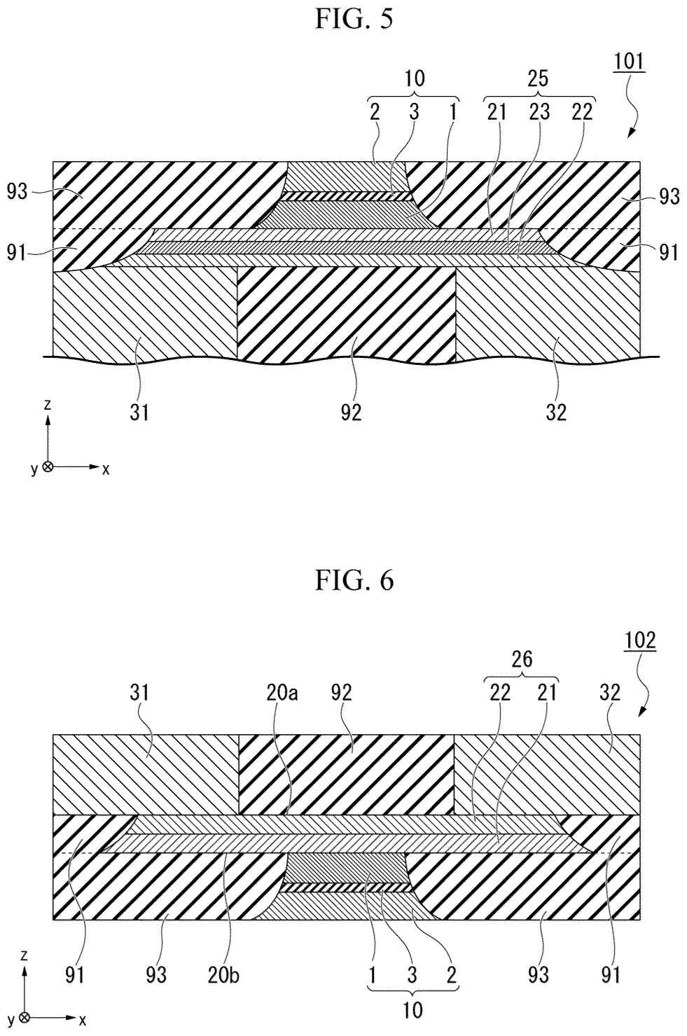

FIG. 5 is a cross-sectional view of a magnetoresistance effect element 101 according to a first modification example. FIG. 5 shows an xz cross section that passes through the center of a spin-orbit torque wiring 25 in the y direction. In FIG. 5, the same configurations as those in FIG. 3 are denoted by the same reference numerals, and descriptions thereof will be omitted.

In the magnetoresistance effect element 101 according to the first modification example, the configuration of the spin-orbit torque wiring 25 is different from the spin-orbit torque wiring 20 of the magnetoresistance effect element 100.

The spin-orbit torque wiring 25 has the first layer 21, the second layer 22 and an intermediate layer 23. The intermediate layer 23 is disposed between the first layer 21 and the second layer 22. The intermediate layer 23 contains a material different from that of the first layer 21 and the second layer 22.

When the intermediate layer 23 is disposed, the number of interfaces between different layers within the spin-orbit torque wiring 25 increases. When the number of interfaces between different layers increases, an amount of spins injected from the spin-orbit torque wiring 25 into the first ferromagnetic layer 1 increases due to the Rashba effect.

The intermediate layer 23 contains, for example, a ferromagnetic material. When the intermediate layer 23 contains a ferromagnetic material, a spin current can be generated more efficiently due to the anomalous spin Hall effect. The thickness of the intermediate layer 23 is, for example, 1 nm or less. When the intermediate layer 23 is sufficiently thin, such as 1 nm or less, no magnetization occurs in the intermediate layer 23 containing a ferromagnetic material. The anomalous spin Hall effect occurs even when no magnetization occurs. Since the intermediate layer 23 has no magnetization, the intermediate layer 23 does not generate a magnetic field. Therefore, there is no need to consider the effects of a leakage magnetic field and the like.

In addition, the intermediate layer 23 may be made of, for example, a non-magnetic component. The intermediate layer 23 contains, for example, any one of the group consisting of Ir, Ru, Rh, Cr, Cu, Re, Pd, Pt, and Au. These elements have a large spin-orbit interaction, and can efficiently generate a spin current even in the intermediate layer 23.

The magnetoresistance effect element 101 according to the first modification example can achieve the same effects as the magnetoresistance effect element 100 according to the first embodiment. In addition, since the spin-orbit torque wiring 25 has the intermediate layer 23, a spin current can be generated more efficiently.

### Second Modification Example

FIG. 6 is a cross-sectional view of a magnetoresistance effect element 102 according to a second modification example. FIG. 6 shows an xz cross section that passes through the center of a spin-orbit torque wiring 26 in the y direction. In FIG. 6, the same configurations as those in FIG. 3 are denoted by the same reference numerals, and descriptions thereof will be omitted.

The laminate 10 shown in FIG. 6 has a bottom pin structure in which the magnetization fixed layer (the second ferromagnetic layer 2) is close to the substrate Sub. When the magnetization fixed layer is on the side of the substrate Sub, the stability of the magnetization of the magnetization fixed layer increases, and the MR ratio of the magnetoresistance effect element 102 increases. The spin-orbit torque wiring 26 is, for example, on the laminate 10. The first layer 21 is closer to the first ferromagnetic layer 1 than the second layer 22, and the second layer 22 is on the first layer 21. The first wiring 31 and the second wiring 32 are on the spin-orbit torque wiring 26.

The magnetoresistance effect element 102 according to the second modification example differs only in the positional relationship of respective configurations, and can achieve the same effects as the magnetoresistance effect element 100 according to the first embodiment.

### Second Embodiment

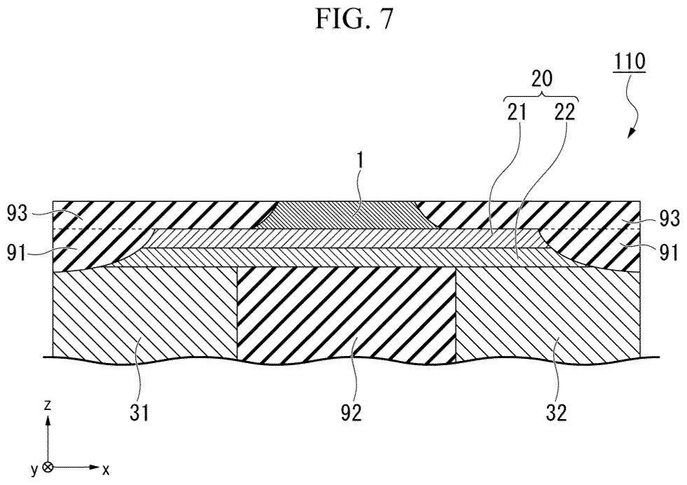

FIG. 7 is a cross-sectional view of a magnetization rotation element 110 according to a second embodiment. In FIG. 7, the magnetization rotation element 110 is replaced with the magnetoresistance effect element 100 according to the first embodiment.

For example, the magnetization rotation element 110 allows light to enter the first ferromagnetic layer 1, and evaluates the light reflected by the first ferromagnetic layer 1. When the orientation direction of the magnetization changes due to the magnetic Kerr effect, the polarization state of the reflected light changes. For example, the magnetization rotation element 110 can be used as an optical element, for example, a video display device that utilizes a difference in the polarization state of light.

In addition, the magnetization rotation element 110 can be used alone as an anisotropic magnetic sensor, an optical element using the magnetic Faraday effect or the like.

The spin-orbit torque wiring 20 of the magnetization rotation element 110 has the first layer 21 and the second layer 22.

The magnetization rotation element 110 according to the second embodiment is the same as the magnetoresistance effect element 100 except that the non-magnetic layer 3 and the second ferromagnetic layer 2 are removed, and can achieve the same effects as the magnetoresistance effect element 100 according to the first embodiment.

While preferable aspects of the present disclosure have been exemplified above based on the first embodiment, the second embodiment and the modification examples, the present disclosure is not limited to these embodiments. For example, feature configurations of respective embodiments and modification examples may be applied to other embodiments and modification examples.

### REFERENCE SIGNS LIST

1 First ferromagnetic layer
2 Second ferromagnetic layer
3 Non-magnetic layer
10 Laminate
20 Spin-orbit torque wiring
21 First layer
22 Second layer
23 Intermediate layer
31 First wiring
32 Second wiring
91 First insulating layer
92 Second insulating layer
93 Third insulating layer
100, 101, 102 Magnetoresistance effect element
110 Magnetization rotation element
200 Magnetic memory
CL Common wiring
RL Read wiring
WL Write wiring
In Insulating layer

1. A magnetization rotation element comprising
a spin-orbit torque wiring; and
a first ferromagnetic layer connected to the spin-orbit torque wiring,
wherein the spin-orbit torque wiring has a first layer and a second layer,
wherein the first layer is closer to the first ferromagnetic layer than the second layer,
wherein the first layer has a negative spin Hall angle,
wherein the second layer has a positive spin Hall angle, and
wherein at least one of the first layer and the second layer is nitride.

2. The magnetization rotation element according to claim 1,
wherein the first layer contains a metal element belonging to any one of the group consisting of Group 3, Group 4, Group 5 and Group 6, and
wherein the second layer contains a metal element belonging to any one of the group consisting of Group 8, Group 9, Group 10, Group 11 and Group 12.

3. The magnetization rotation element according to claim 1,
wherein the second layer contains a light element with an atomic number of 38 or less.

4. The magnetization rotation element according to claim 1,
wherein at least one of the first layer and the second layer contains nitrogen or carbon.

5. The magnetization rotation element according to claim 4,
wherein the contents of nitrogen and carbon in the second layer are all 50 atm % or less.

6. The magnetization rotation element according to claim 1, further comprising an intermediate layer between the first layer and the second layer.

7. The magnetization rotation element according to claim 6,
wherein the intermediate layer contains a ferromagnetic material.

8. The magnetization rotation element according to claim 7,
wherein the thickness of the intermediate layer is 1 nm or less.

9. The magnetization rotation element according to claim 6,
wherein the intermediate layer contains any one of the group consisting of Ir, Ru, Rh, Cr, Cu, Re, Pd, Pt, and Au.

10. A magnetoresistance effect element, comprising the magnetization rotation element according to claim 1, a non-magnetic layer, and a second ferromagnetic layer,
wherein the non-magnetic layer is interposed between the first ferromagnetic layer and the second ferromagnetic layer, and
wherein the first ferromagnetic layer is closer to the spin-orbit torque wiring than the second ferromagnetic layer.

11. A magnetic memory comprising the plurality of magnetoresistance effect elements according to claim 10.

12. The magnetization rotation element according to claim 1,
wherein both the first layer and the second layer are nitride.

13. The magnetization rotation element according to claim 1,
wherein the first layer is TaN and the second layer is TiN.

14. A magnetization rotation element comprising
a spin-orbit torque wiring; and
a first ferromagnetic layer connected to the spin-orbit torque wiring,
wherein the spin-orbit torque wiring has a first layer and a second layer,
wherein the first layer is closer to the first ferromagnetic layer than the second layer,
wherein the first layer has a negative spin Hall angle,
wherein the second layer has a positive spin Hall angle,
wherein at least one of the first layer and the second layer contains oxygen, and
wherein the content of oxygen in at least one of the first layer and the second layer is 30 atm % or more and 50 atm % or less.

15. A magnetization rotation element comprising
a spin-orbit torque wiring; and
a first ferromagnetic layer connected to the spin-orbit torque wiring,
wherein the spin-orbit torque wiring has a first layer and a second layer,
wherein the first layer is closer to the first ferromagnetic layer than the second layer,
wherein the first layer has a negative spin Hall angle,
wherein the second layer has a positive spin Hall angle,
wherein at least one of the first layer and the second layer contains nitrogen or carbon, and
wherein the content of nitrogen or carbon in at least one of the first layer and the second layer is 50 atm % or less.
